(19) United States
(12) Patent Application Publication
(10) Pub. No.: US 2014/0230878 A1
(43) Pub. Date: Aug. 21, 2014

(54) METHOD FOR ELECTRICALLY CONNECTING SEVERAL SOLAR CELLS AND PHOTOVOLTAIC MODULE

(71) Applicants: Henning Schulte-Huxel, Hannover (DE); Susanne Blankemeyer, Bad Pyrmont (DE); Rolf Brendel, Hameln (DE); Robert Bock, Erfurt (DE); Thorsten Dullweber, Hameln (DE); Nils-Peter Harder, Hameln (DE); Carsten Hampe, Hameln (DE); Yevgeniya Larionova, Ronnenberg (DE)

(72) Inventors: Henning Schulte-Huxel, Hannover (DE); Susanne Blankemeyer, Bad Pyrmont (DE); Rolf Brendel, Hameln (DE); Robert Bock, Erfurt (DE); Thorsten Dullweber, Hameln (DE); Nils-Peter Harder, Hameln (DE); Carsten Hampe, Hameln (DE); Yevgeniya Larionova, Ronnenberg (DE)

(73) Assignee: INSTITUT FÜR SOLARENERGIEFORSCHUNG GMBH, Emmerthal (DE)

(21) Appl. No.: 14/125,869

(22) PCT Filed: Jun. 13, 2012
(86) PCT No.: PCT/EP2012/061225

§ 371 Date: Mar. 21, 2014

(30) Foreign Application Priority Data
Jun. 14, 2011 (DE) 10 2011 104 159.5

(51) Int. Cl. H01L 25/04; H01L 31/02

(52) U.S. Cl. CPC H01L 25/042; H01L 31/02008
USPC 136/244; 438/67

(57) ABSTRACT

The invention relates to a method for metallizing and connecting solar cell substrates and to a photovoltaic module made of several metallized solar cells that are electrically connected to one another. According to the invention, a solar cell substrate, in which second metal layers forming electrical metal contacts are optionally provided, is attached to a carrier substrate, on the surface of which at least one first metal layer is formed in a suitable pattern. By localized irradiation of the metal layer with laser radiation through the solar cell substrate or the carrier substrate, energy is introduced such that the metal layer is heated by absorbed laser radiation for an irreversible bonding to the adjacent surface of the solar cell substrate. By the laser bonding of the metal layer on the carrier substrate to the solar cell substrate, solar cells can be connected to form a photovoltaic module.

### FIELD OF THE INVENTION

The present invention concerns a method for metallising and electrically connecting several solar cells. The invention also concerns a photovoltaic module constructed accordingly.

### TECHNICAL BACKGROUND

Substrates for solar cells must frequently be metallised on their surface, for example to allow an electrical contact with the solar cells and in particular to be able to connect different solar cells together electrically. A metallising of solar cells should firstly be mechanically resistant and hence for example be stable over a typical life of solar cell modules of e.g. 30 years, in order to keep degradation effects as low as possible. Secondly by means of the metallisation, a good electrical contacting of the solar cell substrates should be achieved with minimum possible electrical resistance. Also the metallisation should be performed reliably and economically on an industrial scale.

For the production of photovoltaic modules, several solar cells were previously connected together, usually thermically, by metal strips in a standard industrial process and connected together into a module. A electrical contacting between the solar cells in serial or parallel via the metal strips was usually achieved by infrared soldering or conventional soldering.

During the soldering process, thermal stresses in the layer connection of the solar cells or in the metallisation for connecting several solar cells together may lead to damage or destruction. This may be critical in particular in wafer-based solar cells, the thickness of which should fall, as a cost reduction measure, from the present approximately 200 μm to in future less than 50 μm with the same efficiency. With such thin solar cells, because of the fragility of the wafers, during soldering increased breakage rates occur which may require the development of alternative metallisation methods.

New cell designs, which for example have both contact types on the same surface of the solar cell, may also require new damage-reduced and cost-efficient methods for metallising and hence electrical contacting and connection.

In addition, the interconnection of solar cells using metal strips to be soldered may make a substantial contribution to the cost of production of photovoltaic modules because of the high work complexity and because of the materials to be used for metallisation. In order to be able to solder the individual solar cells for example with the metal strip, solderable contacts must be provided at the solar cells. As standard for this, industrial solar cells are generally metallised with silver-based, screen-printed paste. Because of a strong rise in the raw material price for silver, alternative materials are sought for metallising solar cells. Insofar however as these themselves are not solderable, previously a complex and cost-intensive application of further metallic, solderable layers was required.

### SUMMARY OF THE INVENTION

There may therefore be a need for a method for metallising and electrical connection of solar cells, for example a method for interconnecting solar cells into a photovoltaic module, in which in particular the deficiencies described above of conventional metallisation processes may be overcome or reduced. In particular there may be a need for a reliable, economic metallisation method for solar cells and/or one which can be achieved easily on an industrial scale. Furthermore there may be a need for a photovoltaic module which, in particular because of its production-related structure, allows improved reliability with high efficiency and low production costs.

Such needs can be covered with the method and photovoltaic module according to the independent claims. Advantageous embodiments of the invention are defined in the dependent claims.

According to a first aspect of the present invention, a method is proposed for metallising and electrically connecting several solar cells. The method has the following method steps: provision of several solar cell substrates; provision of a carrier substrate which on one surface carries at least one first metal layer which is fixedly connected with the carrier substrate; laying of the solar cell substrates each with a surface of a solar cell substrate adjacent to the first metal layer on the carrier substrate; application of energy to the metal layer by local irradiation with laser radiation, such that the laser radiation is transmitted through at least one of the solar cell substrate and/or carrier substrate in a direction towards the metal layer, and that the first metal layer is irreversibly connected with the adjacent solar cell substrate due to the heating from the absorbed laser radiation.

This aspect of the invention can be regarded inter alia as based on the following concept: it has been found that solar cells may be metallised and hence electrically contacted in that a surface of the solar cell substrate is laid on a metal layer and is brought mechanically into contact therewith, and the metal layer is then irradiated using a laser such that it is greatly heated locally. The metal layer heated in this way may thus be bonded with the surface of the solar cell substrate, i.e. a mechanically adhesive and electrically conductive, irreversible connection to the latter may be created. The fact that the connection is irreversible may be expressed in that the connection cannot be released again without damaging at least one of the components participating in the connection. As will be described in more detail below, in such a bonding or connection, a temporary liquefaction of metal from the metal layer may occur, may correspond to laser welding. As explained in more detail below, in contrast to the soldering method, there is no need for low-melting additional materials with a liquefaction temperature of for example less than 500° C. The laser welding can be an embodiment of a fusion-welding process in which at least one, preferably both of the components to be connected are heated to above their liquefaction temperature and may be connected together integrally after subsequent solidification of the melt. While the components to be joined are held in contact together and where applicable a pressure is built up from one component to the other, the energy necessary for heating the components is not supplied by mechanical pressure, as for example in friction welding, but may be provided by means of laser radiation. Alternatively the laser radiation for the bonding process may be adapted such that it leads to a sintering together of the metal layer and the surface of the solar cell substrate, or to formation of the liquid eutectic phase between the metal layer and the surface of the solar cell substrate. The laser radiation may be irradiated such that it radiates through the solar cell substrate and/or through the carrier substrate, wherein the properties of the laser radiation used should be selected such that the material of the respective substrate is largely transparent to the laser radiation, and hence a substantial absorption of the laser radiation only occurs at the metal layer.

The metallisation method proposed allows a reliable, economic, rapid and simple metallisation and electrical contracting of solar cell substrates.

Further possible details and advantages of embodiments of the proposed metallisation and connection methods are described below.

The solar cell substrate provided may consist of an arbitrary semiconductor material. The metallisation method is suitable in particular for metallising thin silicon wafers with a thickness for example less than 200 μm, preferably less than 100 μm, since high mechanical stresses on the solar cell substrate are avoided.

The terms “solar cell” and “solar cell substrate” are here used similarly. A solar cell substrate may be a partly processed semiconductor substrate, in which amongst others a pn transition, dielectric layers and where applicable even parts of the metallisation are already formed. A solar cell should be understood as a finished, processed unit and may be integrated as such in a photovoltaic module.

The carrier substrate provided may consist of various materials. In particular it may be preferred to form the carrier substrate of an electrically non-conductive i.e. insulating material. For example glass, flexible polymers or other non-conductive layers may be used for the carrier substrate. The carrier substrate may consist of a thin film and hence be mechanically flexible, or for example be provided in the form of a glass plate and hence be mechanically stiff. In particular it may be advantageous to use for the carrier substrate materials which are already used for example in the production of photovoltaic modules. In particular films made of ethylene vinyl acetate (EVA) or silicone may be used for the carrier substrate.

The carrier substrate may in particular be formed 2-dimensional and have a larger surface than the solar cell substrates applied thereto, so that with a single carrier substrate, several solar cell substrates may be metallised and electrically connected together.

A metal layer is provided on the surface of the carrier substrate and is referred to herein as the first metal layer. This first metal layer may be applied to the carrier substrate before this is brought into contact with the solar cell substrate. The first metal layer may lie directly adjacent to the non-metallic carrier substrate, i.e. without the interposition of other, in particular metal layers. The first metal layer may be deposited on the carrier substrate or applied thereto such that it is fixedly connected to the carrier substrate, i.e. it may not be detached from the carrier substrate without damage. Alternatively the first metal layer may be deposited on or applied to the carrier substrate by adhesion such that it indeed remains securely on the carrier substrate before bonding of the metal layer to the surface of the solar cell substrate, but after such bonding, the adhesion of the metal layer to the surface of the solar cell substrate is greater than that to the carrier substrate, so that the carrier substrate may be detached from the metal layer.

In principle the carrier substrate may be coated with the first metal layer over the entire surface. It may however be preferred if the carrier substrate is coated with a metal only locally, for example through a mask, or if parts of the metal layer initially deposited over the entire surface are removed locally, so that the first metal layer is composed as a pattern of several metal layer regions. For example firstly a metal layer may be deposited on the surface of the carrier substrate over a large area, and then the regions which form a pattern of the first metal layer and which shall be bonded to the solar cell substrate, for example by means of a laser, may be separated from the surrounding regions. The surrounding regions may then be removed before bonding of the regions of the metal layer to be applied to the cell substrate. Alternatively the surrounding regions may also remain on the surface of the solar cell substrate, wherein after bonding of the regions of the metal layer to be applied to the solar cell substrate, the carrier substrate may be detached again together with the unbonded surrounding regions, wherein the bonded regions of the metal layer detach from the carrier substrate and remain on the solar cell substrate.

The pattern of the first metal layer may here be adapted, using the first metal layer, not only for example for metallising different solar cell substrates but also to connect these together electrically via the first metal layer. The first metal layer may here have a layer thickness in the range from 30 nm to 300 μm, preferably in the range from 100 nm to 100 μm. The layer thickness used for the first metal layer may be selected according to an electrical resistance to be achieved via the metal layer.

In principle any metal may be used for the first metal layer. It may however be preferred to use an economic metal and/or one which liquefies at low temperatures. For example a metal may be used with a liquidus temperature indeed lying above a temperature for example of 500° C., for example above 570° C., and which therefore may not be melted with conventional soldering methods, but the liquidus temperature of which however lies below a temperature of for example 1600° C. and which therefore may be melted relatively easily by irradiation with laser light. Furthermore the metal may be applied to the carrier substrate easily, for example with conventional vapour deposition methods or printing methods. Furthermore the metal should have a sufficiently high electrical conductivity for the connection of several solar cell substrates. The metal for the first metal layer need not be solderable. Aluminium has proved advantageous for the first metal layer. Aluminium is admittedly not solderable but may be made available and processed economically, and has already for some time proved suitable in particular for the contacting of silicon solar cell substrates. Other metals preferred for solar cell production which may be used for the first metal layer are, amongst others, silver (Ag), copper (Cu), titanium (Ti), nickel (Ni), gold (Au) and palladium (Pd).

The carrier substrate equipped with the first metal layer and the solar cell substrate to be metallised are laid against each other as part of the metallisation process such that the surface of the solar cell substrate to be metallised lies adjacent to the first metal layer of the carrier substrate, i.e. is in mechanical contact therewith or is arranged closely adjacent thereto.

A laser beam is then directed onto the solar cell substrate or carrier substrate such that laser radiation reaches the interface between the solar cell substrate and the carrier substrate and is there absorbed by the first metal layer or a second metal layer, described further below, so greatly that the first metal layer is irreversibly bonded directly to the adjacent solar cell substrate because of the heating achieved by the absorption of the laser radiation, i.e. the first metal layer creates a connection with the semiconductor material of the solar cell substrate or with the metal of a second metal layer provided thereon, wherein the connection cannot be separated again without damage. Such a connection is also referred to partly below as a “bonded connection”, and the process of heating and joining by means of laser radiation is also called “bonding”.

Properties of the laser radiation e.g. its wavelength, power density and where applicable pulse duration, should be selected such that in the material of the solar cell substrate or carrier substrate through which the laser radiation must first be transmitted, there is no substantial absorption of the laser radiation, i.e. for example heating the material significantly. In particular the properties of the laser radiation used may be selected such that on the irradiation of the metal layer, no damaging heating of the solar cell substrate occurs which would cause a reduction in the efficiency of the finished, metallised solar cell. The use of a pulsed laser has proved advantageous for low-damage bonding.

Furthermore it may be advantageous to select the properties of the laser radiation such that a local liquefaction of the metal layer occurs temporarily by the absorption of the laser radiation in the metal layer.

In particular the intensity and a pulse duration of the laser radiation used may be selected such that a sufficiently large quantity of laser radiation is absorbed in the metal layer to heat this, for at least part of the time, above the melt temperature or liquidus temperature of the metal layer. The metal layer then liquefies briefly locally and on subsequent solidification, may form a mechanically and electrically reliable, bonded contact with the adjacent surface of the solar cell substrate or a second metal layer previously deposited thereon.

Alternatively, properties of the laser radiation may be selected such that the metal layer is heated by the absorption not to exceed the melt or liquidus temperature but to exceed an eutectic temperature at which the metal layer forms a liquid eutectic phase with the semiconductor material of the adjacent solar cell substrate. Whereas for example the melt temperature of aluminium is 660° C., the eutectic temperature, at which aluminium forms a liquid phase with silicon, is already reached at 577° C., so that with this particular material combination, a lower laser radiation absorption or laser beam intensity may suffice.

As a further alternative, in the case of specific material combinations it may suffice to heat the metal layer by laser beam absorption only until a sintering process occurs, in which a bonded connection is achieved by diffusion of atoms between the first metal layer and the solar cell substrate or a further second metal layer deposited on the solar cell substrate.

In the process of laser bonding, in particular laser welding or laser sintering, in which the first metal layer previously deposited on the carrier substrate is bonded to the solar cell substrate and in this way an electrical contact is created, it may be provided that the first metal layer comes into direct contact with the surface of the adjacent solar cell substrate and creates an irreversible connection with this material.

As already stated, alternatively a second metal layer may be formed on the surface of the solar cell substrate. This second metal layer may cover the surface of the solar cell substrate entirely or locally with a pattern. For solar cells for example it is provided that locally metallised regions are provided at contact regions to the base or emitter regions of the solar cell substrate. Conventionally, for this normally metal is vapour-deposited or printed on locally. For the bonding process, the laser beam may then be directed through the solar cell substrate or carrier substrate such that it is absorbed in the first metal layer and/or in the second metal layer and at least one of these two metal layers is heated sufficiently for an irreversible connection.

An important possible advantage of the metallisation method described may be found in that for the bonding process between the surface of the solar cell substrate and the adjacent first metal layer, or in the case that a second metal layer is provided on the solar cell substrate, between the first metal layer and the adjacent second metal layer, no additional material need be interposed which has a liquefaction temperature, i.e. a melt temperature or liquidus temperature, which is lower, preferably substantially lower, for example by more than 50° C., than the liquefaction temperature of the metal of the first metal layer or first and second metal layer. In particular no electrically conductive additional material need be interposed. Furthermore, in particular in the regions in which the solar cell substrate or the second metal layer provided thereon is irreversibly joined to the first metal layer, no electrically conductive material need be provided such as for example a solder material. In other words, because of the generation of high temperatures possible by absorption of laser radiation in one of the metal layers, it is possible to join this for example by liquefaction directly, i.e. integrally, by material connection to the adjacent surface of the solar cell substrate or adjacent second metal layer, without a low-melting additional material being required, such as is necessary in conventional solder processes. All materials participating in the electrical connection between the solar cell substrate and the first metal layer, which may serve inter alia for connection of several solar cell substrates, may therefore be high-melting i.e. the liquefaction temperatures of all participating materials may e.g. lie above 500° C., preferably above 570° C.

Insofar as a first metal layer is provided on the carrier substrate and also a second metal layer is provided on the solar cell substrate, both these metal layers may consist of the same material. For example both metal layers may consist of aluminium. Here therefore a benefit may be obtained from the fact that aluminium may not be soldered conventionally since an oxide layer rapidly forms on the surface, which layer may be detached for example with a flux medium, but the laser bonding process proposed here is able to connect the two aluminium layers with mechanical adhesion and electrical conductivity.

The term “metal” here should be broadly understood and includes both pure metal and also metal mixtures, metal alloys and stacks of different metal layers.

According to a further aspect of the present invention, a photovoltaic module is proposed which is made of several metallised solar cells electrically interconnected together. The photovoltaic module has several solar cells and a single carrier substrate. At a surface of the carrier substrate a first metal layer fixedly connected to the carrier substrate is provided. Each of the solar cells is arranged lying with a surface on the metal layer of the carrier substrate and integrally electrically connected to the metal layer at least locally.

Such a photovoltaic module may advantageously be produced using the metallisation method described above.

The phrase “integrally connected locally” may be understood to mean that the metal layer provided on the carrier substrate, which preferably lies directly adjacent to the non-metallic carrier substrate, is connected by material connection to the surface of the semiconductor substrate of the solar cell, or to a metal contact layer previously applied to such a surface, directly i.e. without the interposition of further additional materials, such as for example low-melting, electrically conductive solder materials.

The metallisation method described above and the photovoltaic module which may be produced correspondingly according to various embodiments of the invention allow a number of advantages:

The method allows the metallisation, electrical contacting and mutual connecting of several solar cells virtually simultaneously i.e. in a single method step. Instead of metallising each solar cell individually, as was necessary conventionally when metal strips to be soldered were used to connect together several solar cells, a tabular carrier substrate may be provided with a first metal layer previously deposited thereon in a suitable pattern, in order to metallise a plurality of solar cells within a common processing step using the laser bonding method described and to connect these together by electrical contacting. The process, such as for example connection of several solar cells into a photovoltaic module, may therefore be simplified and made more cost-efficient.

A metallisation can be provided over the entire surface of the carrier substrate or at least over a large part thereof, wherein better transverse conductivities and hence a saving of metal for metallising the solar cells may be achieved.

The use of the laser bonding technology allows metallisation and connection of solar cells using the metallised carrier substrate, without the solar cells having to be exposed to excessive thermal loads.

Furthermore, the laser bonding technology allows a direct connection of a plurality of metals, wherein inter alia non-solderable metals may be electrically and mechanically connected together in this way. Thus traditionally non-solderable aluminium may be used for metallising and connection of solar cells. A direct connection of the first metal layer provided on the carrier substrate to the solar cell substrate, or to a second metal layer previously deposited on this solar cell substrate, is possible without additional adhesives or solder pastes, whereby both process steps and processing material may be saved. The solderable silver metallisation on the solar cell substrate conventionally used for metallising solar cell substrates, or other similar metallisations, may be omitted since solderability of these metallisations is no longer required. Thus substantial costs may be saved.

Because a single type of metal is sufficient for metallising the solar cell substrate when the laser bonding method is used, corrosion phenomena from the contact of various metals of different nobilities can be avoided.

Because a tabular carrier substrate with an also tabular metal layer is used to metallise the solar cell substrate, and the metal layer is bonded to the solar cell substrate distributed over a broad surface, local loads on the solar cell substrate may be kept low. This is advantageous in particular for very thin solar cell substrates which are mechanically fragile.

In particular on the encapsulation of solar cells into photovoltaic modules, the holes generated in the first metal layer on irradiation with the laser may contribute to improved adhesion of the lamination material through penetration of lamination materials into these holes.

In a particular embodiment of the method according to the invention, a layer of polymer material, such as for example a film of ethylene vinyl acetate (EVA) or silicone, may be interposed between the solar cell substrate and the carrier substrate. The layer may serve to seal or fill any cavities in the solar cell substrate. The layer may for example be deformed during encapsulation of the finished solar cells and/or be, brought into contact with similar layers of an encapsulation material. In this way it may largely be avoided that for example moisture penetrates an encapsulated solar cell module, settles in the cavities and leads to corrosion. In regions in which the first metal layer is to be bonded to the surface of solar cell substrate or to a second metal layer provided thereon, the polymer layer may for example be locally interrupted or locally removed during lasering.

By suitable choice of carrier substrate, a flexible structure may be achieved. Thus for example the photovoltaic module may be adapted to widely varying shapes or supports.

Where a self-supporting mechanically stable carrier substrate is used in the proposed metallisation, for example solar cells based on thin wafers may be given mechanical support by the carrier substrate, which may reduce breakage rates in the production of photovoltaic modules.

It is noted that embodiments, features and advantages of the invention are described here partly in relation to the method for metallising and electrical connecting of several solar cells, and partly in relation to a photovoltaic module produced in this way. A person skilled in the art will however recognise that unless specified otherwise, the embodiments and features of the invention may be transferred similarly to the respective other inventive objects. In particular a person skilled in the art will find that features of the various embodiments may be combined in arbitrary fashion.

### BRIEF DESCRIPTION OF THE DRAWINGS

Further features and advantages of the invention will be evident to the person skilled in the art from the description below of exemplary embodiments which should not however be interpreted as restricting the invention, and with reference to the enclosed drawings.

FIG. 1 shows an arrangement of solar cells during metallisation according to one embodiment of the present invention;

FIG. 2 shows an alternative arrangement of solar cells during metallisation according to one embodiment of the present invention;

FIG. 3 shows a further alternative arrangement of solar cells during metallisation according to one embodiment of the present invention;

FIG. 4 shows a top view onto a carrier substrate metallised with a pattern;

FIG. 5 shows a top view onto solar cell substrates previously metallised locally;

FIG. 6 shows a top view of solar cell substrates which have been metallised and electrically connected together using a carrier substrate, according to one embodiment of the present invention.

The details shown in figures are illustrated diagrammatically and are not shown true to scale. Same reference numerals relate to the same or corresponding features in the different figures.

### DETAILED DESCRIPTION OF PREFERRED EMBODIMENTS

FIG. 1 shows an arrangement of several metallised solar cells 20 electrically connected together and formed as a photovoltaic module 100. In the example shown, the solar cells 20 are wafer-based silicon solar cells in which both contact types are arranged on the back of a solar cell substrate 1. Emitter regions of the solar cell are coated with an aluminium metal layer 2a forming a first contact type, while base regions are coated with an aluminium metal layer 2b forming a second contact type.

FIG. 5 shows a top view of the solar cell substrate 1 with the metal layers 2a, 2b forming the different contact types.

For reasons of greater clarity, no further details of the solar cells 20, such as for example differently doped emitter and base regions, surface passivation layers, etc., are shown in the figures.

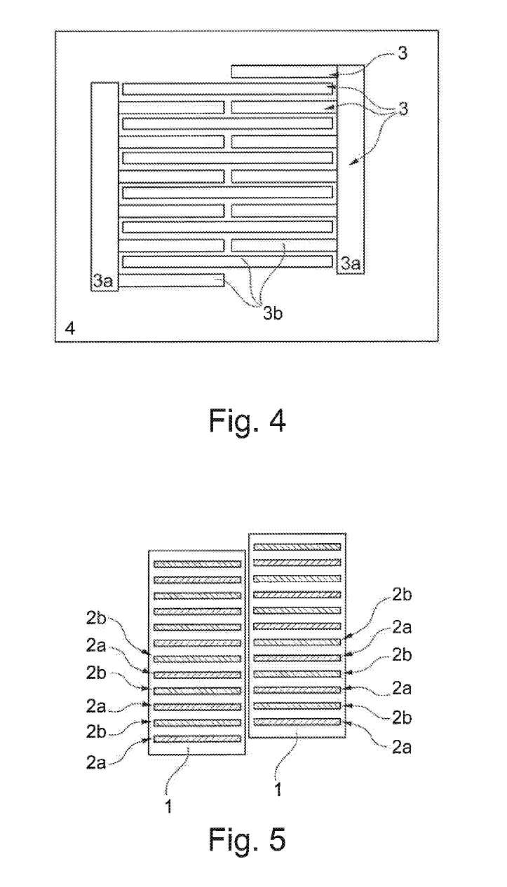

In preparation for a metallisation process, a carrier substrate 4 is coated with a metal layer 3 which also consists of aluminium. As indicated diagrammatically in FIG. 4, the metal layer 3 does not cover the carrier substrate 4 over the entire surface but is formed as a special pattern with collective busbars 3a and longitudinally connecting fingers 3b. The carrier substrate 4 may be a thin flexible film, for example made of EVA, as used conventionally to encapsulate solar cells. Alternatively the carrier substrate 4 may be a rigid glass panel. The metal layer 3 may be applied to the carrier substrate 4 for example using vapour deposition technologies with suitable masks or by printing technologies.

To metallise the solar cell substrates 1 and also to connect the solar cells 20 together, these are laid on the carrier substrate 4. The solar cell substrates 1 are positioned on the carrier substrate 4 so that the metal layers 2a, 2b forming the different contact types at positions provided lie adjacent to the correspondingly formed pattern of the metal layer 3 deposited on the carrier substrate 4.

Then using a laser beam 6, a connecting region 7 is irradiated at which a metal layer 3 of the carrier substrate 4 lies adjacent to a metal layer 2a, 2b of the solar cell substrate 1. For this for example a pulsed Nd-YAG laser can be used which for example emits in a wavelength region of 1064 nm, 532 nm or 355 nm. Laser pulse durations in the range of a few nanoseconds up to a few microseconds have been found suitable. It has also been found that power densities in the range from 0.1 J/cm² to 10 kJ/cm², preferably 0.5 J/cm² to 5 kJ/cm² give advantageous metallisation results. The properties of the laser beams used are adapted thus to the material of the carrier substrate 4 such that the laser radiation 6 is transmitted largely unhindered through the carrier substrate 4 to the metal layer 3.

In the metal layer 3, part of the irradiated laser radiation power is absorbed and thus leads to thermal heating. The metal of the layer 3 is here briefly heated greatly such that an irreversible bonding connection is created with the metal layers 2a, 2b on the solar cell substrate 1.

For this, the metal of the first metal layer 3 may for example be heated beyond its melt point so that in its liquid phase, it may connect integrally by material connection to the adjacent second metal layer 2a, 2b on the solar cell substrate 1. In this case the irradiated laser radiation 6 has the effect of laser welding.

Alternatively the properties of the irradiated laser radiation 6 may be selected such that the first metal layer 3 is heated less strongly, whereby a bonding connection may be created by a form of sintering together of the first metal layer 3 with an adjacent metal layer 2a, 2b on the solar cell substrate 1.

As shown in FIG. 1, the laser radiation 6 transmitted through the carrier substrate 4 may be supplemented or replaced by a laser radiation 5 transmitted for example through the solar cell substrate 1 in the opposite direction. Since the solar cell substrate 1 usually has different absorption properties from the carrier substrate 4, the properties of the laser radiation 5 used here must be adapted accordingly, to ensure that the laser radiation 5 is transmitted largely through the solar cell substrate 1 and is then absorbed in the metal layer 2a, 2b deposited thereon.

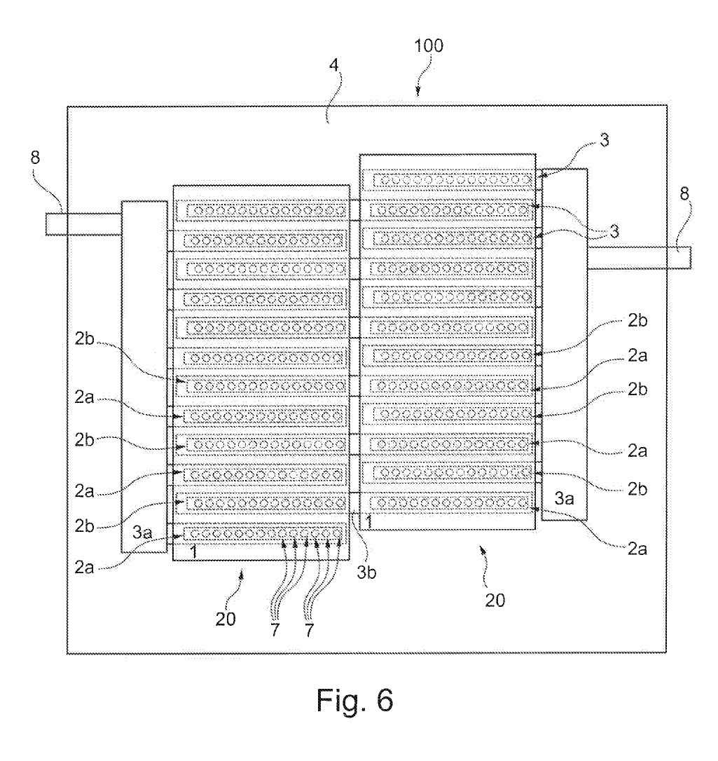

FIG. 6 shows diagrammatically a top view of the arrangement shown in FIG. 1 of several cells 20. The solar cells 20 in which, as shown in FIG. 5, metallisations 2a, 2b are formed for the different contact types, are arranged on a carrier substrate 4. The solar cells 20 are positioned such that the metal layer regions 2a, 2b are arranged above correspondingly metallised regions 3b of the carrier substrate 4, as shown in FIG. 4. Both metal layers 2, 3 here consist of aluminium. At a multiplicity of connecting regions 7, the laser bonding method described above forms connection points through which each of the solar cells 20 is connected integrally with the metal layer 3 provided on the carrier substrate 4. External connections 8 serve to make the electrical power supplied by the solar cells available to consumers.

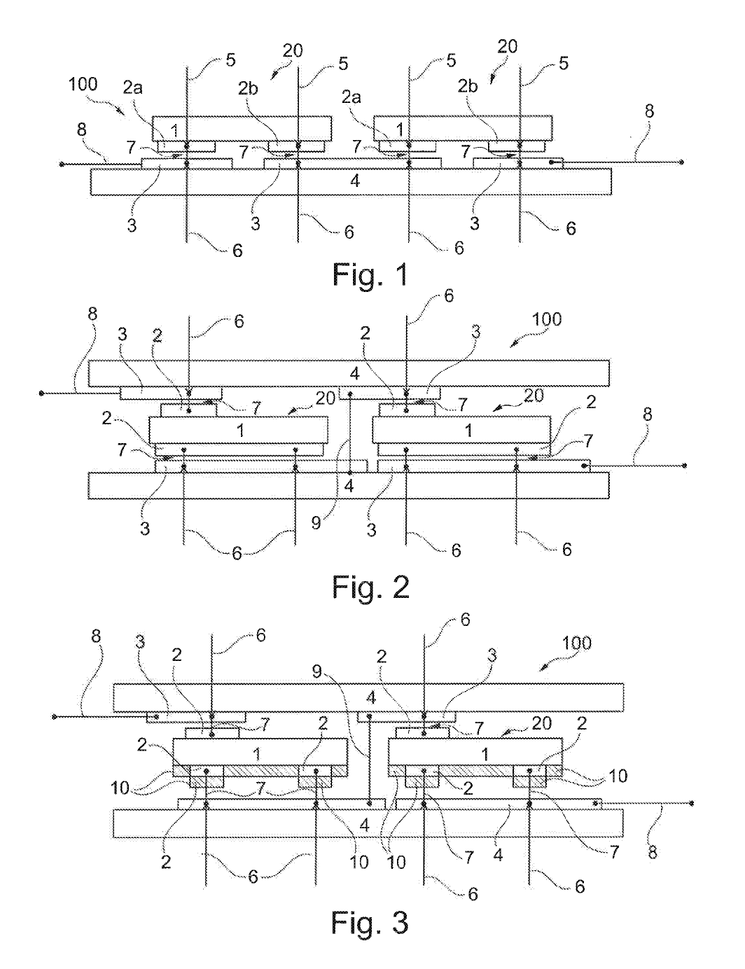

FIGS. 2 and 3 show alternative embodiments of photovoltaic modules 100, as may be produced with the metallisation method described, using laser bonding.

FIG. 2 shows a correspondingly metallised carrier substrate 4 arranged on both sides of a solar cell substrate 1. For example solar cells 20 in which the different contact types are formed on opposite surfaces, may be interposed between two carrier substrates 4. Metal layers 2 on the front and back of the solar cell substrate 1 may then be connected mechanically and electrically to metal layers 3 on the carrier substrate 4 using laser radiation 6 by means of a laser bonding process. For serial connection of the solar cells, internal metal connections 9, which contact adjacent solar cells, may be provided between the metal layers 3. For this for example a metal layer 3 provided on the upper carrier substrate 4 may be connected in a region between two adjacent solar cells 20 directly to a metal layer 3 provided on the lower carrier substrate 4.

FIG. 3 shows a further embodiment of a photovoltaic module 100. As in the embodiment in FIG. 2, solar cells 20 are contacted by carrier substrates 4 on both sides. On a back of the solar cell substrate 1 however a dielectric layer 10 is provided in addition to the metal layers 2. This can for example serve for passivation of the surface of the solar cell substrate 1. Alternatively, in a similar manner, a layer of polymer material can be interposed which can fill or seal any cavities in the finished solar cell, in order to prevent corrosion damage.

It has been found that such a dielectric layer 10, for example around 100 nm thick, may be penetrated during the laser bonding process, and an electric and mechanical connection of the metal layer 2 on the solar cell substrate 1 to a metal layer 3 on the carrier substrate 4 may be achieved.

It is pointed out that a plurality of different embodiments are possible for forming first and second metal layers 2, 3 on the solar cell substrate 1 or on the carrier substrate 4. Furthermore further dielectric layers 10 can be provided at different positions on the solar cell substrate 1, for example above the metal layer 2, between the metal layer 2 and the solar cell substrate 1, etc., on the various surfaces of the solar cell substrate 1. These dielectric layers 10 may serve for passivation of the surface of the solar cell substrate 1 or as an antireflection layer or as an electrically insulating layer, and should not hinder the laser bonding process between the solar cell substrate 1 and the metal layer 3 on the carrier substrate 4.

Finally it is pointed out that in the embodiments shown in the figures, in each case metal layers 2 are already provided on the solar cell substrate 1, with which layers then the metal layers 3 provided on the carrier substrate 4 can form an integral connection during the metallisation process. Since the laser bonding method used allows a use of aluminium for the metal layers 2 on the solar cell substrate 1, this may constitute an embodiment preferred for industrial use.

However metal layers 2 need not necessarily be already provided on the solar cell substrate 1. In embodiments (not shown graphically), the metal layers 3 provided on the carrier substrate 4 may also create a bonding connection directly to the surface of the semiconductor material of the solar cell substrate 1 during the laser bonding process. When aluminium is used for the metal layer 3, it may be particularly advantageous here that aluminium may form a liquid eutectic phase with silicon of a solar cell substrate 1 even below its melt temperature, i.e. above an eutectic temperature, and thus even at lower temperatures an integral electrical connection may be created between the metal layer 3 provided on the carrier substrate 4 and the solar cell substrate 1.

Finally it is pointed out that the terms “comprise”, “have” etc. do not exclude the presence of further elements. The term “a” also does not exclude the presence of a plurality of objects. The reference numerals in the claims serve merely for better legibility and in no way restrict the scope of protection of the claims.

### LIST OF REFERENCE NUMERALS

1 Solar cell substrate
2 Second metal layer
3 First metal layer
4 Carrier substrate
5 Laser radiation
6 Laser radiation
7 Connecting region
8 External connections
9 Internal metal connection
10 Dielectric layer
20 Solar cells
100 Photovoltaic module

1-15. (canceled)

16. Method for metallising and electrically connecting several solar cells, wherein the method comprises:
provision of a carrier substrate which on one surface carries at least one first metal layer fixedly connected to the carrier substrate;
provision of several solar cell substrates, wherein on one surface of at least one solar cell substrate a second metal layer is formed which is fixedly connected to the solar cell substrate;
laying of the solar cell substrates in each case with a surface of a solar cell substrate adjacent to the first metal layer on the carrier substrate;
application of energy to the metal layer by local irradiation of the metal layer by pulsed laser radiation with pulse durations in the range of less than several microseconds, such that the laser radiation is transmitted through at least one of the solar cell substrate and the carrier substrate in a direction towards the first metal layer, and that the first metal layer with the second metal layer is irreversibly connected directly to the adjacent solar cell substrate by heating due to absorbed laser radiation,
wherein between the first metal layer and the adjacent second metal layer, no electrically conductive additional material is interposed with a liquefaction temperature which is substantially lower than the liquefaction temperature of the metals of the first and second metal layers.

17. Method according to claim 16, wherein between the surface of the solar cell substrates and the adjacent first metal layer, no additional material is interposed with a liquefaction temperature which is substantially lower than the liquefaction temperature of the metal of the first metal layer.

18. Method according to claim 16, wherein by the local irradiation with laser radiation, at least one of the first and second metal layers is heated for the irreversible connection.

19. Method according to claim 16, wherein the first and second metal layers consist of the same metal.

20. Method according to claim 16, wherein at least one of the first and the second metal layer has a layer thickness in the range from 50 nm to 300 μm.

21. Method according to claim 16, wherein properties of the laser radiation are selected such that due to absorption of the laser radiation in at least one of the first and second metal layers local liquefaction of the metal layer occurs temporarily.

22. Method according to claim 16, wherein properties of the laser radiation are selected such that on irradiation of the metal layer no damaging heating of the solar cell substrate occurs which could reduce the efficiency of the respective solar cell.

23. Method according to claim 16, wherein the carrier substrate consists of an electrically non-conductive material.

24. Method according to claim 16, wherein the carrier substrate consists of a film.

25. Method according to claim 16, wherein a layer of polymer material is interposed between the solar cell substrate and the carrier substrate.

26. Method according to claim 16, wherein no electrically conductive additional material with a liquefaction temperature of less than 500° C. is interposed.

27. Photovoltaic module of several metallised and electrically connected solar cells, comprising:
several solar cells;
a single carrier substrate which carries on a surface at least one first metal layer fixedly connected to the carrier substrate;
wherein each of the solar cells is arranged laid with a surface on the first metal layer of the carrier substrate; and
wherein each of the solar cells is electrically connected at least locally integrally with the metal layer.

28. Photovoltaic module according to claim 27, wherein between the solar cells and the adjacent first metal layer, no electrically conductive additional material is interposed with a liquefaction temperature which is substantially lower than the liquefaction temperature of the metal of the first metal layer.

29. Photovoltaic module according to claim 27, wherein between the solar cells and the adjacent first metal layer, no additional material is interposed with a liquefaction temperature which is substantially lower than the liquefaction temperature of the metal of the first metal layer.
